(19) United States
(12) Patent Application Publication
(10) Pub. No.: US 2025/0275428 A1
(43) Pub. Date: Aug. 28, 2025

(54) DISPLAY DEVICE

(71) Applicant: LG Display Co., Ltd., Seoul (KR)

(72) Inventors: Kyungha Lee, Paju-si (KR); ChangHyun Song, Paju-si (KR); JaeWon Lee, Paju-si (KR); Seonhee Lee, Paju-si (KR)

(73) Assignee: LG Display Co., Ltd., Seoul (KR)

(21) Appl. No.: 18/988,495

(22) Filed: Dec. 19, 2024

(30) Foreign Application Priority Data
Feb. 28, 2024 (KR) 10-2024-0029002

(51) Int. Cl. H10K 59/80; H10K 59/40

(52) U.S. Cl. CPC H10K 59/873; H10K 59/40

(57) ABSTRACT

A display device can include a substrate having a display area and a non-display area located adjacent to the display area. The substrate includes a substrate extension extending from an optical bezel area to a portion of an optical area, and a substrate protrusion protruding from the substrate extension, thereby preventing moisture penetration while reducing a bezel area.

### CROSS-REFERENCE TO RELATED APPLICATION

This application claims priority to Korean Patent Application No. 10-2024-0029002, filed in the Republic of Korea on Feb. 28, 2024, the entire contents of which is hereby expressly incorporated by reference for all purposes as if fully set forth herein into the present application.

### BACKGROUND

### Field

Embodiments of the present disclosure relate to a display device.

### Discussion of the Related Art

As the information society develops, there is increasing a demand for a display device for displaying images in various forms. Recently, various display devices such as liquid crystal displays and organic light-emitting displays are being utilized.

Since an optical electronic device needs to receive light from the front of a display device, an optical electronic device is installed in a place where a light reception is advantageous. Therefore, a camera (or camera lens) and a detection sensor can be exposed on the front of the display device. As a result, a bezel of the display panel can be widened or a notch is needed to be formed in a display area of the display panel, and the camera or detection sensor can be installed in the notch.

If the bezel is widened or the notch is formed on the front of the display panel, the size of the display area for displaying the image on the display panel can be reduced.

Accordingly, a “Hole in Active Area (HiAA)” type display device can be proposed in which at least a portion of a substrate is removed from the display area of the display panel, and an optical electronic device is disposed so as to overlap with the area where at least a portion of the substrate is removed, thereby increasing the size of the display area.

However, there can be a limitation that cracks can occur in the process of removing a portion of the substrate, or that moisture can penetrate into the area where the substrate was removed, thereby deteriorating the display quality. Therefore, there is a demand for solving this limitation.

### SUMMARY OF THE DISCLOSURE

There can be a limitation that cracks can occur or moisture can penetrate into the display area of the display panel, thereby deteriorating the display quality.

Accordingly, the inventors of the present disclosure have invented a display device capable of preventing the crack occurrence or the moisture penetration so as to preserve the display quality.

Embodiments of the present disclosure can provide a display device having an optical area arranged so as not to expand the width of an optical bezel area.

Embodiments of the present disclosure can provide a display device capable of preventing or minimizing moisture penetration and crack spreading from the optical bezel area to the display area.

Embodiments of the present disclosure can provide a display device capable of removing or minimizing the moisture penetration and crack penetration which can occur in the optical bezel area.

Embodiments of the present disclosure can provide a display device applied by a process optimization in which a dam is formed through a substrate in a process of removing at least a portion of the substrate from the display area and disposing an optical electronic device so as to overlap with the area from which at least a portion of the substrate has been removed.

A display device according to embodiments of the present disclosure can include a substrate including a non-display area having an optical area and an optical bezel area which is an outer area of the optical area, and a display area, a light emitting device disposed in the display area, and an organic layer disposed on the substrate. In addition, the substrate can include a substrate extension extending from the optical bezel area to a portion of the optical area, and a substrate protrusion protruding from the substrate extension in the optical area.

According to embodiments of the present disclosure, it is possible to provide a display device having an optical area arranged so as not to expand the width of an optical bezel area.

According to embodiments of the present disclosure, it is possible to provide a display device capable of preventing or minimizing moisture penetration and crack spreading from the optical bezel area to the display area.

According to embodiments of the present disclosure, it is possible to provide a display device capable of removing or minimizing the moisture penetration and crack penetration which can occur in the optical bezel area.

According to embodiments of the present disclosure, it is possible to provide a display device applied by a process optimization in which a dam is formed through a substrate in a process of removing at least a portion of the substrate from the display area and disposing an optical electronic device so as to overlap with the area from which at least a portion of the substrate has been removed.

### BRIEF DESCRIPTION OF THE DRAWINGS

The present disclsoure will become more fully understood from the detailed description given hereinbelow and the accompanying drawings which are given by way of illustration only, and thus are not limitative of the present disclsoure.

FIG. 1 is a system configuration diagram of a display device according to embodiments of the present disclosure.

FIG. 2 illustrates an equivalent circuit of a subpixel in a display panel according to embodiments of the present disclosure.

FIG. 3 is a cross-sectional view of a display area in a display panel according to embodiments of the present disclosure.

FIG. 4 is a drawing for specifically explaining an optical area.

FIG. 5 is a cross-sectional view of an optical bezel area, along line I-I′ of FIG. 4.

FIGS. 6, 7, and 8 are cross-sectional views of an optical bezel area and an optical area where a substrate protrusion is disposed according to embodiments of the present disclosure.

FIGS. 9, 10, 11, and 12 are cross-sectional views of an optical bezel area and an optical area where a substrate protrusion is disposed in a display panel including a touch sensor according to embodiments of the present disclosure.

### DETAILED DESCRIPTION OF THE EMBODIMENTS

Hereinafter, embodiments of the disclosure are described in detail with reference to the accompanying drawings. In assigning reference numerals to components of each drawing, the same components can be assigned the same numerals even when they are shown on different drawings. When determined to make the subject matter of the disclosure unclear, the detailed of the known art or functions can be skipped. As used herein, when a component “includes,” “has,” or “is composed of” another component, the component can add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” can be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components can be directly “connected”, “coupled” or “linked””, or another component can intervene. Here, the other component can be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it can include a non-continuous relationship unless the term “immediately” or “directly” is used.

Further, the term “can” fully encompasses all the meanings and coverges of the term “may.’

When a component is designated with a value or its corresponding information (e.g., level), the value or the corresponding information can be interpreted as including a tolerance that can arise due to various factors (e.g., process factors, internal or external impacts, or noise).

Hereinafter, various embodiments of the disclosure are described in detail with reference to the accompanying drawings. All the components of each dispay device according to all embodiments of the present disclsoure are operatively coupled and configured.

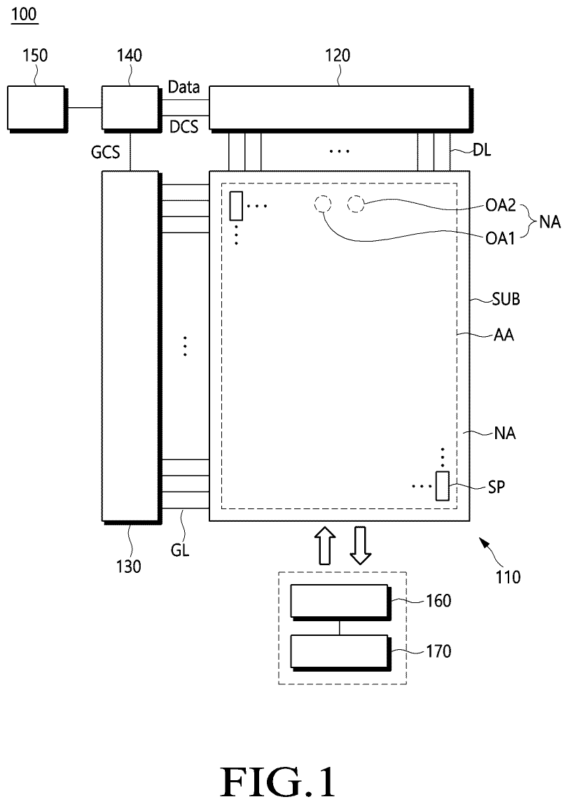

FIG. 1 is a system configuration diagram of a touch display device 100 according to embodiments of the present disclosure.

Referring to FIG. 1, the touch display device 100 can include a display panel 110 and a display driving circuit as components for displaying an image.

The display driving circuit can be a circuit for driving a display panel 110, and can include a data driving circuit 120, a gate driving circuit 130, and a display controller 140.

The display panel 110 can include a display area AA (or active area) where an image is displayed and a non-display area NA (or non-active area) where an image is not displayed. The non-display area NA can be an outer area of the display area AA, and can also be referred to as a bezel area. The non-display area NA can surround the display area AA entirely or only in part(s). All or part of the non-display area NA can be an area visible from the front of the touch display device 100, or can be an area which is bent and not visible from the front of the touch display device 100.

The display panel 110 can include a substrate SUB and a plurality of subpixels SP arranged on the substrate SUB. In addition, the display panel 110 can further include various types of signal lines in order to drive the plurality of subpixels SP.

The display device 100 according to the embodiments of the present disclosure can be a liquid crystal display device, or can be a self-luminous display device in which the display panel 110 emits light by itself. When the display device 100 according to the embodiments of the present disclosure is a self-luminous display device, each of the plurality of subpixels SP can include a light emitting device.

The display device 100 according to the embodiments of the present disclosure can be an organic light-emitting display device in which the light emitting device is implemented as an organic light-emitting diode (OLED). For another example, the touch display device 100 according to the embodiments of the present disclosure can be an inorganic light-emitting display device in which the light emitting device is implemented as an inorganic-based light-emitting diode. For another example, the touch display device 100 according to the embodiments of the present disclosure can be a quantum dot display device in which the light emitting device is implemented as a quantum dot, which is a semiconductor crystal emitting light by itself.

Depending on the type of the display device 100, there can vary the structure of each of the plurality of subpixels SP. For example, if the display device 100 is a self-luminous display device in which the subpixel SP emits light by itself, each subpixel SP can include a light emitting device capable of emitting light by itself, one or more transistors, and one or more capacitors.

For example, signal line of various types can include a plurality of data lines DL which transmit data signals (also referred to as data voltages or image signals) and a plurality of gate lines GL which transmit gate signals (also referred to as scan signals).

The plurality of data lines DL and the plurality of gate lines GL can intersect each other. Each of the plurality of data lines DL can be arranged while extending in a first direction. Each of the plurality of gate lines GL can be arranged while extending in a second direction.

Here, the first direction can be a column direction and the second direction can be a row direction. Alternatively, the first direction can be a row direction and the second direction can be a column direction.

The data driving circuit 120 is a circuit for driving a plurality of data lines DL, and can output the data signal to the plurality of data lines DL. The gate driving circuit 130 is a circuit for driving a plurality of gate lines GL, and can output the gate signal to the plurality of gate lines GL.

The display controller 140 is a device configured to control the data driving circuit 120 and the gate driving circuit 130. The display controller 140 can control the driving timing for the plurality of data lines DL and the driving timing for the plurality of gate lines GL.

The display controller 140 can supply a data driving control signal DCS to the data driving circuit 120 to control the data driving circuit 120, and can supply a gate driving control signal GCS to the gate driving circuit 130 to control the gate driving circuit 130.

The display controller 140 can receive input image data from a host system 150, and supply image data Data to the data driving circuit 120 based on the input image data.

The data driving circuit 120 can supply data signals to a plurality of data lines DL according to the driving timing control of the display controller 140.

The data driving circuit 120 can receive image data in digital form from the display controller 140, convert the received image data into data signals in analog form, and output the converted image data to a plurality of data lines DL.

The gate driving circuit 130 can supply gate signals to a plurality of gate lines GL according to the timing control of the display controller 140. The gate driving circuit 130 can receive a first gate voltage corresponding to a turn-on level voltage and a second gate voltage corresponding to a turn-off level voltage together with various gate driving control signals GCS, generate gate signals, and supply the generated gate signals to a plurality of gate lines GL.

For example, the data driving circuit 120 can be connected to the display panel 110 by a tape automated bonding (TAB) method, or can be connected to a bonding pad of the display panel 110 by a chip-on-glass (COG) or chip-on-panel (COP) method, or can be connected to the display panel 110 by being implemented as a chip-on-film (COF) method.

The gate driving circuit 130 can be connected to the display panel 110 using a tape automated bonding (TAB) method, or can be connected to a bonding pad of the display panel 110 using a chip-on-glass (COG) or chip-on-panel (COP) method, or can be connected to the display panel 110 according to a chip-on-film (COF) method. Alternatively, the gate driving circuit 130 can be a gate-in-panel (GIP) type, and can be formed in the non-display area NA of the display panel 110. The gate driving circuit 130 can be disposed on or connected to the substrate SUB. For example, if the gate driving circuit 130 is of the GIP type, it can be disposed in the non-display area NDA of the substrate SUB. The gate driving circuit 130 can be connected to the substrate in the case of a chip-on-glass (COG) type, chip-on-film (COF) type, etc.

Meanwhile, at least one of the data driving circuit 120 and the gate driving circuit 130 can be disposed in the display area AA. For example, at least one of the data driving circuit 120 and the gate driving circuit 130 can be disposed not to overlap with the subpixels SP, or can be disposed to partially or entirely overlap with the subpixels SP.

The data driving circuit 120 can be connected to one side (e.g., the upper side or the lower side) of the display panel 110. Depending on the driving method, panel design method, etc., the data driving circuit 120 can be connected to both sides (e.g., the upper side and the lower side) of the display panel 110, or can be connected to two or more sides among the four sides of the display panel 110.

The gate driving circuit 130 can be connected to one side (e.g., the left side or the right side) of the display panel 110. Depending on the driving method, panel design method, etc., the gate driving circuit 130 can be connected to both sides (e.g., the left side and the right side) of the display panel 110, or can be connected to two or more sides among the four sides of the display panel 110.

The display controller 140 can be implemented as a separate component from the data driving circuit 120, or can be implemented as an integrated circuit integrated with the data driving circuit 120.

The display controller 140 can be a timing controller used in typical display technology, or can be a control device capable of further performing other control functions including a timing controller, or can be a control device different from the timing controller, or can be a control device other than a timing controller, or can be a circuit within the control device. The display controller 140 can be implemented with various circuits or electronic components, such as an integrated circuit (IC), a field programmable gate array (FPGA), an application specific integrated circuit (ASIC), or a processor.

The display controller 140 can be mounted on a printed circuit board, a flexible printed circuit, etc., and can be electrically connected to the data driving circuit 120 and the gate driving circuit 130 through a printed circuit board, a flexible printed circuit.

The display controller 140 can transmit and receive signals with the data driving circuit 120 according to one or more predetermined interfaces. For example, the interface can include a low voltage differential signaling (LVDS) interface, an embedded clock point-point interface (EPI) interface, or a serial peripheral interface (SPI).

The display device 100 according to the embodiments of the present disclosure can include one or more optical areas OA from which at least a portion of the substrate SUB is removed.

One or more optical electronic devices can be disposed in an area overlapping with at least a portion of the optical area OA. The one or more optical electronic devices can include, for example, one or more of an imaging device such as a camera (e.g., image sensor), a detection sensor such as a proximity sensor, and an illuminance sensor, etc.

For example, an imaging device such as a camera can be positioned below a first optical area OA1, and a detection sensor can be positioned below a second optical area OA2.

The optical electronic device can be positioned below the substrate SUB, and the optical electronic device can be positioned to overlap with at least a portion of the optical area OA.

The first optical area OA1 and the second optical area OA2 can have various shapes, such as circular, oval, square, hexagonal, or octagonal. The shapes of the first optical area OA1 and the second optical area OA2 can be the same, but can also be different. The area of the first optical area OA1 can be the same as the area of the second optical area OA2, but can also be different.

Hereinafter, for convenience of explanation, it will be described a case in which the first optical area OA1 and the second optical area OA2 have circular shapes and have the same area, but the embodiments of the present disclosure are not limited thereto.

Meanwhile, one or more optical areas OA can be located in an area where the substrate SUB is removed, and such optical areas OA can be non-display areas NA where subpixels SP are not disposed.

The optical area OA located within a display area AA can be also referred to as a “HiAA (Hole in Active Area)” area.

The signal lines (e.g., data lines DL, gate lines GL, etc.) disposed on the substrate SUB can be arranged around (or bypassing) the optical area OA.

In order to provide a touch sensing function in addition to an image display function, the display device 100 according to the embodiments of the present disclosure can include a touch sensor and and a touch sensing circuit which senses a touch sensor to detect whether a touch has occurred by a touch object such as a finger or pen, or to detect a touch location.

The touch sensing circuit can include a touch driving circuit 160 for driving and sensing the touch sensor to generate and output touch sensing data, and a touch controller 170 for detecting touch occurrence or detecting a touch location using the touch sensing data.

The touch sensor can include a plurality of touch electrodes. The touch sensor can further include a plurality of touch lines for electrically connecting the plurality of touch electrodes and the touch driving circuit 160.

The touch sensor can be located outside the display panel 110 or inside the display panel 110.

If the touch sensor is located outside the display panel 110 in the form of a panel, the touch sensor is referred to as an external type. If the touch sensor is an external type, a touch panel and the display panel 110 can be manufactured separately and combined during the assembly process. An external type touch panel can include a substrate and a plurality of touch electrodes on the substrate.

If the touch sensor is located inside the display panel 110, the touch sensor can be formed on the substrate SUB together with signal lines and electrodes related to display driving during the manufacturing process of the display panel 110.

The touch driving circuit 160 can supply a touch driving signal to at least one of the plurality of touch electrodes, and sense at least one of the plurality of touch electrodes to generate touch sensing data.

The touch sensing circuit can perform touch sensing in a self-capacitance sensing manner or a mutual-capacitance sensing manner.

When the touch sensing circuit performs touch sensing in a self-capacitance sensing manner, the touch sensing circuit can perform touch sensing based on the capacitance between each touch electrode and a touch object (e.g., a finger, a pen, etc.).

According to the self-capacitance sensing manner, each of the plurality of touch electrodes can act as a driving touch electrode and also act as a sensing touch electrode. The touch driving circuit 160 can drive all or part of the plurality of touch electrodes and sense all or part of the plurality of touch electrodes.

When the touch sensing circuit performs touch sensing using a mutual-capacitance sensing manner, the touch sensing circuit can perform touch sensing based on the capacitance between the touch electrodes.

According to the mutual-capacitance sensing manner, a plurality of touch electrodes can be divided into driving touch electrodes and sensing touch electrodes. The touch driving circuit 160 can drive the driving touch electrodes and sense the sensing touch electrodes.

The touch driving circuit 160 and the touch controller 170 included in the touch sensing circuit 150 can be implemented as separate devices or can be implemented as one device. In addition, the touch driving circuit 160 and the data driving circuit 120 can be implemented as separate devices or can be implemented as one device.

The display device 100 can further include a power supply circuit which supplies various types of power to the display driving circuit and/or the touch sensing circuit.

The display device 100 according to the embodiments of the present disclosure can be a mobile terminal such as a smart phone or a tablet, or a monitor or television (TV) of various sizes, and is not limited thereto, and can be a display of various types and sizes capable of displaying information or images.

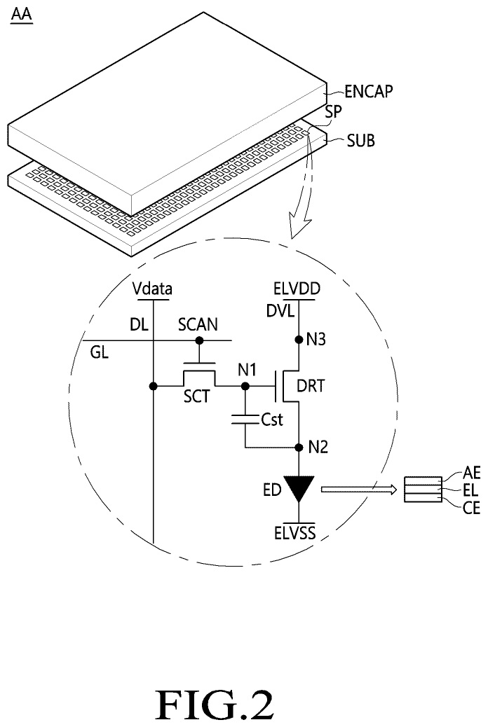

FIG. 2 illustrates an equivalent circuit of a subpixel SP in a display panel 110 according to embodiments of the present disclosure.

Referring to FIG. 2, each of the subpixels SP disposed in the display area AA of the display panel 110 can include a light emitting device ED, a driving transistor DRT for driving the light emitting device ED, a scan transistor SCT for transmitting a data voltage Vdata to a first node N1 of the driving transistor DRT, and a storage capacitor Cst for maintaining a constant voltage during one frame.

The driving transistor DRT can include a first node N1 to which a data voltage Vdata is applied, a second node N2 electrically connected to the light emitting device ED, and a third node N3 to which a high-potential common voltage ELVDD is applied from a driving voltage line DVL. In the driving transistor DRT, the first node N1 can be a gate node, the second node N2 can be one of a source node or a drain node, and the third node N3 can be the other of the source node or the drain node.

The light emitting device ED can include an anode electrode AE, an emission layer EL and a cathode electrode CE. The anode electrode AE can be a pixel electrode arranged in each subpixel SP, and can be electrically connected to the second node N2 of the driving transistor DRT of each subpixel SP. The cathode electrode CE can be a common electrode disposed in common to a plurality of subpixels SP, and supplied with a low-potential common voltage ELVSS.

For example, the anode electrode AE can be a pixel electrode, and the cathode electrode CE can be a common electrode. Alternatively, the anode electrode AE can be a common electrode, and the cathode electrode CE can be a pixel electrode. In the following, for convenience of explanation, it is assumed that the anode electrode AE is a pixel electrode, and the cathode electrode CE is a common electrode.

For example, the light emitting device ED can be an organic light emitting diode (OLED), an inorganic light emitting diode, or a quantum dot light emitting device. In this case, if the light emitting device ED is an organic light emitting diode, the emission layer EL in the light emitting device ED can include an organic emission layer containing an organic material.

The scan transistor SCT can be turned on and off by a scan signal SCAN, which is a gate signal applied through a gate line GL. The scan transistor SCT can switch an electrical connection between the first node N1 of the driving transistor DRT and the data line DL.

The storage capacitor Cst can be electrically connected between the first node N1 and the second node N2 of the driving transistor (DRT).

Each subpixel SP can have a 2T (Transistor)-1C (Capacitor) structure including two transistors DRT and SCT and one capacitor Cst, and can further include one or more transistors or one or more capacitors, depending on the case.

The storage capacitor Cst can be an external capacitor intentionally designed outside the driving transistor DRT, rather than a parasitic capacitor (e.g., Cgs, Cgd) that can exist between the first node N1 and the second node (N2) of the driving transistor DRT.

Each of the driving transistor DRT and the scan transistor SCT can be an n-type transistor or a p-type transistor.

Since the circuit elements (particularly, light emitting decvice ED) within each subpixel SP are vulnerable to external moisture or oxygen, an encapsulation layer ENCAP can be disposed on the display panel 110 to prevent external moisture or oxygen from penetrating into the circuit elements (particularly, light emitting device ED). The encapsulation layer ENCAP can be disposed in a form of covering the light emitting device ED.

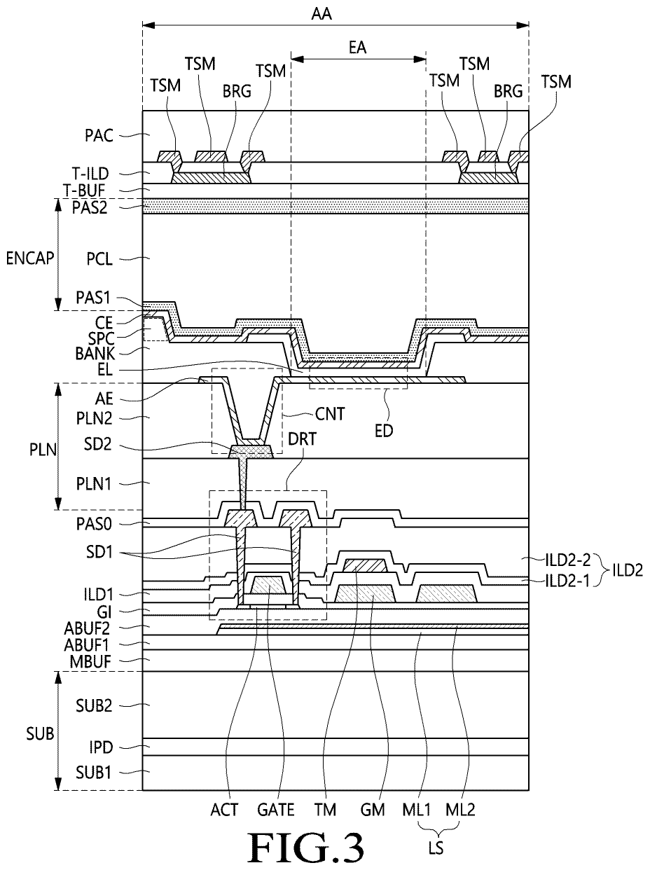

FIG. 3 is a cross-sectional view of a display area AA in a display panel 110 according to embodiments of the present disclosure.

Referring to FIG. 3, the substrate SUB can include a first substrate SUB1, an interlayer insulating film IPD, and a second substrate SUB2. The interlayer insulating film IPD can be located between the first substrate SUB1 and the second substrate SUB2. Since the substrate SUB is configured to include the first substrate SUB1, the interlayer insulating film IPD and the second substrate SUB2, there can be prevented the moisture penetration. For example, the first substrate SUB1 and the second substrate SUB2 can be polyimide PI substrates. The first substrate SUB1 can be referred to as a primary PI substrate, and the second substrate SUB2 can be referred to as a secondary PI substrate.

However, the configuration of the substrate SUB is not limited thereto. For example, the substrate SUB can be a single glass material substrate SUB. Alternatively, the substrate SUB can be a single plastic material substrate SUB.

There can be disposed various patterns ACT, SD1 and GATE, various insulating films MBUF, ABUF1, ABUF2, GI, ILD1, ILD2 and PAS0, and various metal patterns TM, GM, ML1 and ML2 on the substrate SUB in order to form transistors such as driving transistors DRT.

A multi-buffer layer MBUF can be disposed on a second substrate SUB2, and a first active buffer layer ABUF1 can be disposed on the multi-buffer layer MBUF.

A first metal layer ML1 and a second metal layer ML2 can be disposed on the first active buffer layer ABUF1. Here, the first metal layer ML1 and the second metal layer ML2 can be light shield layers LS for shielding light.

A second active buffer layer ABUF2 can be disposed on the first metal layer ML1 and the second metal layer ML2. An active layer ACT of a driving transistor DRT can be disposed on the second active buffer layer ABUF2.

A gate insulating film GI can be disposed while covering the active layer ACT.

A gate electrode GATE of a driving transistor (DRT) can be disposed on the gate insulating film GI. In this case, a gate material layer GM can be disposed on the gate insulating film GI together with the gate electrode GATE of the driving transistor DRT at a position different from the formation position of the driving transistor DRT.

A first interlayer insulating film ILD1 can be disposed while covering the gate electrode GATE and the gate material layer GM. A metal pattern TM can be disposed on the first interlayer insulating film ILD1. The metal pattern TM can be located at a different location from the formation location of the driving transistor DRT. A second interlayer insulating film ILD2) can be disposed while covering the metal pattern TM on the first interlayer insulating film ILD1.

Two first source-drain electrode patterns SD1 can be disposed on the second interlayer insulating film ILD2. One of the two first source-drain electrode patterns SD1 can be a source node of the driving transistor DRT, and the other can be a drain node of the driving transistor DRT.

The two first source-drain electrode patterns SD1 can be electrically connected to one side and the other side of the active layer ACT through contact holes of the second interlayer insulating film ILD2, the first interlayer insulating film ILD1, and the gate insulating film GI.

Meanwhile, the second interlayer insulating film ILD2 can include a second-1 interlayer insulating film ILD2-1 and a second-2 interlayer insulating film ILD2-2. The second-1 interlayer insulating film ILD2-1 can be positioned while covering the metal pattern TM. The second-2 interlayer insulating film ILD2-2 can be positioned on the second-1 interlayer insulating film ILD2-1.

A portion of the active layer ACT overlapping with the gate electrode GATE can be a channel region. One of the two first source-drain electrode patterns SD1 can be connected to one side of the channel region in the active layer ACT, and the other of the two first source-drain electrode patterns SD1 can be connected to the other side of the channel region in the active layer ACT.

A passivation layer PAS0 can be disposed while covering two first source-drain electrode patterns SD1. A planarization layer PLN can be disposed on the passivation layer PAS0. The planarization layer PLN can include a first planarization layer PLN1 and a second planarization layer PLN2.

The first planarization layer PLN1 can be disposed on the passivation layer PAS0.

A second source-drain electrode pattern SD2 can be disposed on the first planarization layer PLN1. The second source-drain electrode pattern SD2 can be connected to one of the two first source-drain electrode patterns SD1 (corresponding to the second node N2 of the driving transistor DRT in the subpixel SP of FIG. 2) through a contact hole of the first planarization layer PLN1.

The second planarization layer PLN2 can be disposed while covering the second source-drain electrode pattern SD2. A light emitting device ED can be disposed on the second planarization layer PLN2.

As the stacked structure of the light emitting device ED, an anode electrode AE can be disposed on the second planarization layer PLN2. The anode electrode AE can be electrically connected to the second source-drain electrode pattern SD2 through a contact hole of the second planarization layer PLN2.

A bank BANK can be disposed to cover a porion of the anode electrode AE. A part of the bank BANK corresponding to the emission area EA of the subpixel SP can be opened. Here, the bank BANK can further include a spacer SPC.

A part of the anode electrode AE can be exposed to an opening (i.e., open portion) of the bank BANK. An emission layer EL can be located on a side of the bank BANK and in the opening (i.e., open portion) of the bank BANK. All or a part of the emission layer EL can be located between adjacent banks BANK.

In the opening of the bank BANK, the emission layer EL can be in contact with the anode electrode AE. A cathode electrode CE can be disposed on the emission layer EL.

The light emitting device ED can be formed by an anode electrode AE, an emission layer EL, and a cathode electrode CE. The emission layer EL can include an organic film.

An encapsulation layer ENCAP can be disposed on the light emitting device ED.

The encapsulation layer ENCAP can have a single-layer structure or a multi-layer structure. For example, as illustrated in FIG. 3, the encapsulation layer ENCAP can include a first encapsulation layer PAS1, a second encapsulation layer PCL, and a third encapsulation layer PAS2.

For example, the first encapsulation layer PAS1 and the third encapsulation layer PAS2 can be inorganic films, and the second encapsulation layer PCL can be an organic film. Among the first encapsulation layer PAS1, the second encapsulation layer PCL, and the third encapsulation layer PAS2, the second encapsulation layer PCL can be the thickest. Accordingly, the second encapsulation layer PCL can serve as a planarization layer. The first encapsulation layer PAS1 can be also referred to as a first inorganic encapsulation layer, the second encapsulation layer PCL can be also referred to as an organic encapsulation layer, and the third encapsulation layer PAS2 can be also referred to as a second inorganic encapsulation layer.

The first encapsulation layer PAS1 can be disposed on the cathode electrode CE, and can be disposed closest to the light emitting device ED. The first encapsulation layer PAS1 can be formed of an inorganic insulating material capable of low-temperature deposition. For example, the first encapsulation layer PAS1 can be made of silicon nitride (SiNx), silicon oxide (SiOx), silicon oxynitride (SiON), or aluminum oxide (Al2O3). Since the first encapsulation layer PAS1 can be deposited in a low-temperature atmosphere, the first encapsulation layer PAS1 can prevent the emission layer EL including an organic material vulnerable to a high-temperature atmosphere from being damaged during the deposition process.

The second encapsulation layer PCL can be formed with a smaller area than the first encapsulation layer PAS1. In this case, the second encapsulation layer PCL can be formed to expose both ends of the first encapsulation layer PAS1. The second encapsulation layer PCL can act as a buffer to relieve stress between each layer due to bending of the display device 100, and can also act to enhance flattening performance. For example, the second encapsulation layer PCL can be made of an acrylic resin, an epoxy resin, a polyimide, polyethylene, or silicon oxycarbon (SiOC), and can be formed of an organic insulating material. For example, the second encapsulation layer PCL can be formed through an inkjet method.

The third encapsulating layer PAS2 can be formed on the substrate SUB on which the second encapsulating layer PCL is formed to cover the upper surface and the side surface of each of the second encapsulating layer PCL and the first encapsulating layer PAS1. The third encapsulating layer PAS2 can minimize or block external moisture or oxygen from penetrating into the first encapsulating layer PAS1 and the second encapsulating layer PCL. For example, the third encapsulating layer PAS2 can be formed of an inorganic insulating material such as silicon nitride (SiNx), silicon oxide (SiOx), silicon oxynitride (SiON), or aluminum oxide (Al2O3).

If the touch sensor TS is of a type built into the display panel 110, the touch sensor TS can be disposed on the encapsulation layer ENCAP. The touch sensor structure is described in detail as follows.

A touch buffer film T-BUF can be disposed on the encapsulation layer ENCAP. The touch sensor TS can be disposed on the touch buffer film T-BUF.

The touch sensor TS can include a touch sensor metal TSM and a bridge metal BRG located in different layers.

A touch interlayer insulating film T-ILD can be disposed between the touch sensor metal TSM and the bridge metal BRG.

For example, the touch sensor metal TSM can include a first touch sensor metal TSM, a second touch sensor metal TSM, and a third touch sensor metal TSM which are disposed adjacent to each other. If it is required for the third touch sensor metal TSM to be disposed between the first touch sensor metal TSM and the second touch sensor metal TSM, and the first touch sensor metal TSM and the second touch sensor metal TSM are required to be electrically connected to each other, the first touch sensor metal TSM and the second touch sensor metal TSM can be electrically connected to each other through a bridge metal BRG in a different layer. The bridge metal BRG can be insulated from the third touch sensor metal TSM by a touch interlayer insulating film T-ILD.

When a touch sensor TS is formed on a display panel 110, a chemical solution (e.g., developing solution or etching solution, etc.) used in the process can be introduced or moisture can be introduced from the outside. Since the touch sensor TS is disposed on the touch buffer film T-BUF, the chemical solution or moisture can be prevented from penetrating into the emission layer EL containing an organic material during the manufacturing process of the touch sensor TS. Accordingly, the touch buffer film T-BUF can prevent the emission layer EL vulnerable to the chemical solution or moisture from being damaged.

The touch buffer film T-BUF can be formed of an organic insulating material capable of being formed at a low temperature (e.g., 100 degrees (° C.) or lower) and having a low permittivity of 1 to 3 in order to prevent damage to the emission layer EL containing an organic material vulnerable to high temperatures. For example, the touch buffer film T-BUF can be formed of an acrylic series, an epoxy series, or a siloxane series material. As the display device 100 is bent, the encapsulation layer ENCAP can be damaged and the touch sensor metal positioned on the touch buffer film T-BUF can be broken. Even if the display device 100 is bent, the touch buffer film T-BUF having flattening performance made of an organic insulating material can prevent damage to the encapsulation layer ENCAP and/or breakage of the metal (e.g., TSM and BRG) forming the touch sensor TS.

A protective layer PAC can be disposed while covering the touch sensor TS. The protective layer PAC can be an organic insulating film.

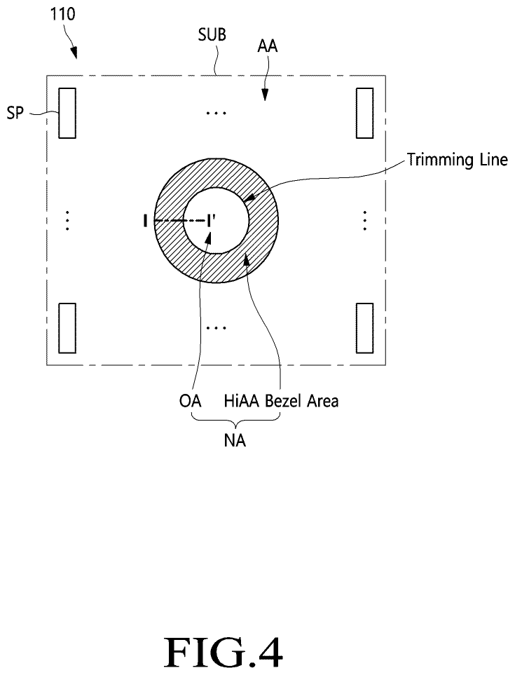

FIG. 4 is a drawing for specifically explaining an optical area OA.

Referring to FIG. 4, the substrate SUB can be cut along an inner trimming line as a cutting line, and the cut area can form an optical area OA.

A HiAA optical bezel area (hereinafter, also abbreviated as an optical bezel area) can be located around the optical area OA on the substrate SUB. The subpixels are not disposed in the optical bezel area, and the optical bezel area can be a non-display area NA similar to the optical area OA.

The optical bezel area can be configured to prevent moisture penetration that can occur along the cutting line (e.g., inner trimming line) and to prevent micro cracks that can occur during the process of forming the optical area OA from penetrating or spreading into the display area AA.

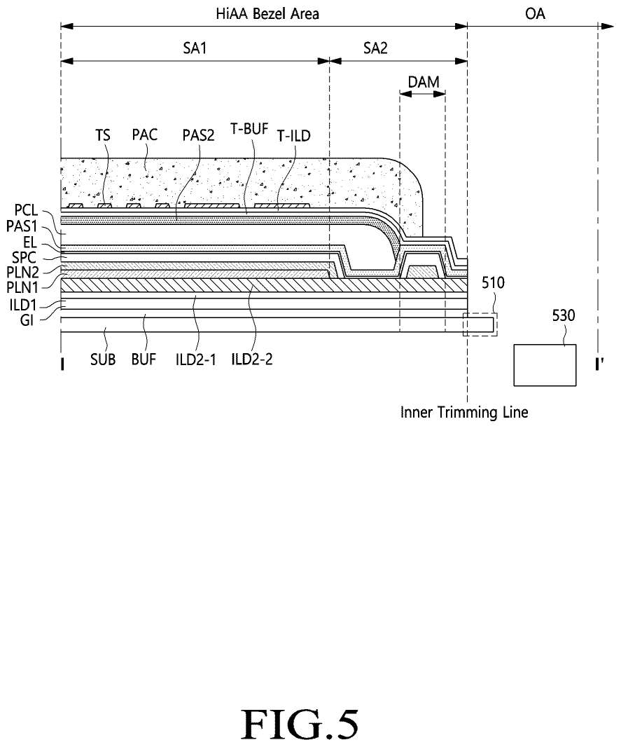

FIG. 5 is a cross-sectional view of the optical bezel area, along line I-I′ of FIG. 4.

Referring to FIG. 5, the substrate SUB can be disposed in front of the optical bezel area (e.g., HiAA bezel area). In addition, there can be disposed a substrate extension 510, which is a part of a substrate SUB disposed to extend to a part of the optical area OA adjacent to the optical bezel area (e.g., HiAA bezel area).

However, the shape and arrangement of the substrate extension 510 are only examples for convenience of explanation, and are not limited thereto. For example, the substrate extension 510 can be a portion of the substrate SUB which is not completely removed during the trimming process for forming the optical area OA. Alternatively, the substrate extension 510 can be formed by curing a paste of the same material as the substrate SUB on the trimmed section of the substrate SUB after trimming the substrate SUB.

Meanwhile, a dam DAM can be positioned in the optical bezel area, and the dam DAM can include at least one dam structure. The dam DAM can be disposed in the optical bezel area to prevent overflow of the second encapsulation layer PCL.

An optical electronic device 530 can be disposed to overlap with at least a portion of the optical area OA.

Meanwhile, referring to FIG. 5, the optical bezel area can include a first sub-area SA1, and a second sub-area SA2 positioned from the first sub-area SA1 toward the optical area OA.

At least one touch sensor TS for touch sensing can be disposed in the first sub-area SA1. The first sub-area SA1 can be an area overlapping with the second planarization layer PLN2 in the optical bezel area (e.g., HiAA bezel area). The touch sensor TS can be covered with a protective layer PAC.

In FIG. 5, for convenience of explanation, the touch sensor TS is illustrated as being disposed on a touch insulating film T-ILD. In an actual configuration, a touch interlayer insulating film T-ILD can be disposed between the touch sensor metal TSM and the bridge metal BRG included in the touch sensor TS.

The dam DAM can be disposed in the second sub-area SA2. The protective layer PAC can extend from the first sub-area SA1 to at least a portion of the second sub-area SA2.

One end of the protective layer PAC can be located on the dam DAM.

Meanwhile, it is preferable that the protective layer PAC does not extend to the optical area OA. Since the protective layer PAC includes an organic material, the protective layer PAC can be a path for moisture penetration. Therefore, one end of the protective layer PAC can be located in the first sub-area SA1 or on the dam DAM as in FIG. 5.

Moisture can penetrate through various paths at the cutting line (e.g., inner trimming line), which is the boundary between the optical bezel area (e.g., HiAA bezel area) and the optical area OA. For example, moisture can penetrate through the second encapsulating layer PCL containing an organic material. The penetrated moisture can penetrate into the thin film transistor or the emission layer, thereby deteriorating the performance of the display device.

In addition, a configuration arranged as an inorganic insulating film, such as a buffer layer BUF, can function as a crack transmission path. If a crack occurs during the process of forming the optical area OA by removing at least a portion of the substrate SUB in the optical area OA, the crack can penetrate into the display area through the inorganic insulating film.

In order to prevent such moisture penetration and crack penetration, there is a need for the width of the optical bezel area (e.g., HiAA bezel area) to be expanded widely to arrange various patterns. However, if the width of the optical bezel area (e.g., HiAA bezel area) is expanded, the display area AA can be reduced by the expanded width, and the non-display area NA on the display panel 110 can be expanded, which can restrict the design of the display device 100 or reduce the aesthetics of the display device.

The display device 100 according to the embodiments of the present disclosure can provide a structure capable of preventing moisture penetration and crack penetration into the display area AA without expanding the width of the optical bezel area (e.g., HiAA bezel area) widely.

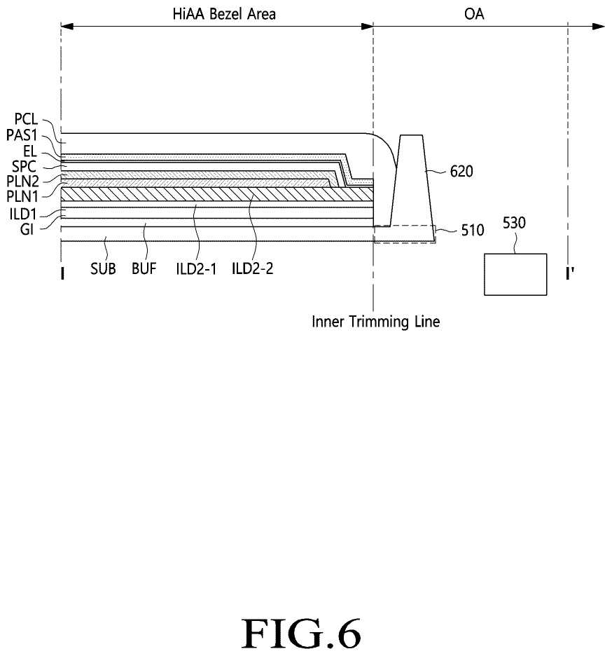

FIGS. 6, 7, and 8 are cross-sectional views of an optical bezel area (e.g., HiAA bezel area) and an optical area OA where substrate protrusions 620, 720 and 820 are disposed according to embodiments of the present disclosure.

Referring to FIG. 6, the substrate SUB can be disposed in the optical bezel area (e.g., HiAA bezel area) and a part of the optical area OA. The substrate SUB can include a substrate extension 510 extending from the optical bezel area to a part of the optical area OA, and a substrate protrusion 620 protruding from the substrate extension 510.

For example, the substrate protrusion 620 can be formed by raising the substrate extension 510 by applying heat with a laser.

The substrate protrusion 620 can be disposed in a dam shape on the substrate extension 510. For example, the substrate protrusion 620 can be formed in a trapezoidal dam shape in which a length of a lower region, which is an area adjacent to the substrate extension 510, is longer and a length of an upper region is shorter. In addition, the substrate protrusion 620 can be disposed so that its height is longer than its width.

However, this is only an example of the shape of the substrate protrusion 620, and the shape of the substrate protrusion 620 is not limited thereto. For example, the substrate protrusion 620 can be disposed in shapes such as a triangle, a rectangle, and an oval.

In a left optical bezel area (e.g., HiAA bezel area) of the substrate protrusion 620, there can be disposed configurations for forming a display panel 110 on the substrate SUB.

For example, as shown in FIG. 6, a buffer layer (BUF) can be disposed in the optical bezel area on the substrate SUB. A gate insulating film GI can be disposed on the buffer layer BUF. An interlayer insulating film ILD1 can be disposed on the gate insulating film GI. A planarization layer PLN1 and PLN2 can be disposed on an interlayer insulating film ILD1. A spacer SPC can be disposed on the planarization layer PLN1 and PLN2. The spacer SPC can have the same configuration as the bank BANK. An emission layer EL can be disposed on the spacer SPC. A first encapsulation layer PAS1 and a second encapsulation layer PCL can be disposed on the emission layer EL.

The configurations disposed on the optical bezel area described above can be configurations disposed from the display area AA to the left optical bezel area of the substrate protrusion 620 as shown in FIG. 6.

An optical area OA can be formed on the right side of the substrate protrusion 620 based on FIG. 6. An optical electronic device 530 can be disposed in the optical area OA. An optical electronic device 530 can be disposed in the optical area OA at the lower right side of the substrate protrusion 620.

The second encapsulation layer PCL disposed on the left side of the substrate protrusion 620 can be formed to fill the gap between the substrate protrusion 620 and the optical bezel area (e.g., HiAA bezel area). For example, the second encapsulation layer PCL, which is an organic layer, can be in contact with a portion of an upper surface of the substrate extension 510 of the optical area OA. In this case, since the substrate protrusion 620 is disposed in the form of a dam, it is possible to prevent the problem of the second encapsulation layer PCL overflowing into the optical area OA on the right side of the substrate protrusion 620.

The substrate protrusion 620 can be disposed so that the height of an upper surface is higher than a point where the second encapsulation layer PCL contacts a side surface of the substrate protrusion 620. Since the second encapsulation layer PCL is formed after forming the substrate protrusion, the second encapsulation layer PCL can be disposed so as to rise from the lower area of the side surface of the substrate protrusion 620.

The substrate protrusion 620 can block the optical bezel area from the optical area OA, thereby preventing moisture penetration through the components disposed in the optical bezel area without expanding the optical bezel area.

Meanwhile, a substrate protrusion 720 can be configured to be solid by penetrating into a crack or a lifted portion formed in a component on the substrate SUB and filling the empty space caused by the crack or the lifted portion.

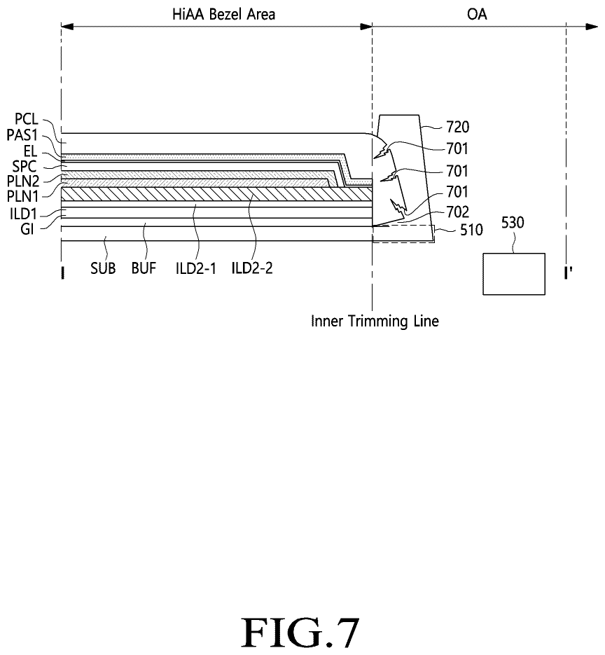

Referring to FIG. 7, the configuration shown in FIG. 7 can be the same as the configuration shown in FIG. 6. The substrate protrusion 720 can also be disposed in the same area as the substrate protrusion 620 shown in FIG. 6.

The shape and arrangement characteristics of the substrate protrusion 720 can be the same as the substrate protrusion 620 shown in FIG. 6. However, the substrate protrusion 720 can be formed after the second encapsulation layer PCL is disposed.

For example, the second encapsulation layer PCL, which is an organic layer, can be disposed on a first encapsulation layer PAS1 before disposing the substrate protrusion 720. The second encapsulation layer PCL can be disposed from the optical bezel area to an upper surface of the substrate extension 510 of the optical area OA.

During the process of forming the display panel 110 after the second encapsulation layer PCL is disposed, the second encapsulation layer PCL, which is an organic layer, can shrink due to factors such as heat and pressure. For example, during the process of forming the optical area OA after disposing the second encapsulation layer PCL, the second encapsulation layer PCL can shrink due to heat generated. Due to the shrinkage, the second encapsulation layer PCL can cause a crack at a first point 701 and a lifting at a second point 702. The lifting at the second point 702 can correspond to a point where the substrate extension 510 and the second encapsulation layer PCL are separated from the optical area OA and lifted.

The substrate protrusion 720 can be disposed in the optical area OA to fill the first point 701 and the second point 702 of the second encapsulation layer PCL. For example, the substrate protrusion 720 can be positioned to fill the first point 701 and the second point 702, the second point 702 is formed by applying heat with a laser to the extension 510 to raise the substrate extension 510. For example, the substrate protrusion 720 can be disposed to cover a portion of the side surface of the second encapsulation layer PCL, which is an organic layer. The substrate protrusion 720 can be disposed to be raised in a dam shape.

Referring to FIG. 7, the substrate protrusion 720 can be disposed in a dam shape similar to the substrate protrusion 620 of FIG. 6. For example, the substrate protrusion 720 can be disposed in a trapezoidal dam shape in which a length of the lower area adjacent to the substrate extension 510 is greater than a length of the upper area. In addition, the substrate protrusion 720 can be disposed to have a height greater than a width.

However, this is only an example of the shape of the substrate protrusion 720, and the shape of the substrate protrusion 720 is not limited thereto. For example, the substrate protrusion 720 can be disposed in shapes such as triangles, rectangles, and ovals.

Alternatively, a substrate protrusion 820 can be disposed in a shape other than a dam.

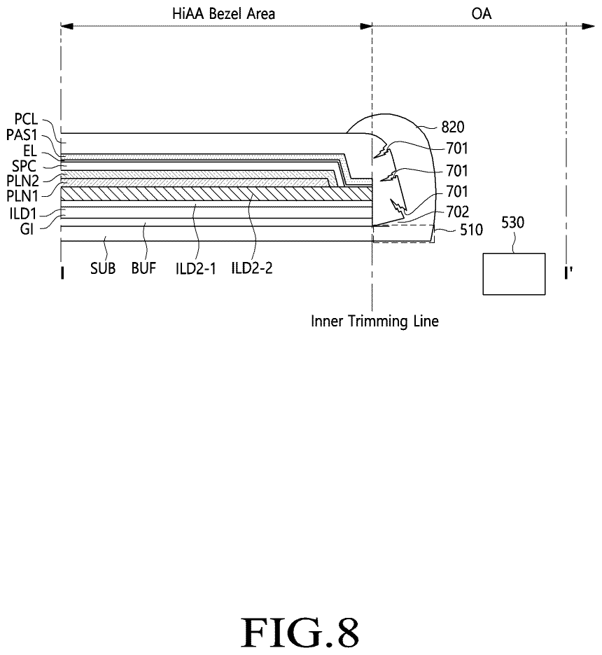

Referring to FIG. 8, a substrate protrusion 820 can be formed by applying paste to a substrate extension 510 and then curing the applied paste. The paste can be the same material as the substrate SUB. For example, the substrate SUB can be a glass material. The paste applied to the substrate extension 510 can also be a fine raw material of glass material. After applying the paste, which is a fine raw material of glass material, to the substrate extension 510, heat can be applied to melt the paste. In this case, a laser can be used as a means for heat-treating the paste. The paste heat-treated by the laser on the substrate extension 510 can be melted and physically bonded to the second encapsulation layer PCL. After the paste is heat-treated, the paste can undergo a hardening process to form a strong bonding structure with the second encapsulation layer PCL.

The features of the configurations shown in FIG. 8 can be the same as the features of the configurations shown in FIG. 7, except for the substrate protrusion 820. For example, with reference to FIG. 8, a buffer layer BUF, a gate insulating film GI, an interlayer insulating film ILD1, planarization layers PLN1 and PLN2, a spacer SPC, an emission layer EL, and an encapsulating layer ENCAP can be disposed on the left side of the substrate protrusion 820.

In FIG. 8, an optical area OA can be formed on the right side of the substrate protrusion 820. An optical electronic device 530 can be located on the lower right optical area OA of the substrate protrusion 820.

The substrate protrusion 820 can be formed after the second encapsulation layer PCL, which is an organic layer, is disposed, similar to the substrate protrusion 720 described in FIG. 7.

For example, the second encapsulation layer PCL, which is an organic layer, can be disposed on the first encapsulation layer PAS1 before disposing the substrate protrusion 820. The second encapsulation layer PCL can be disposed from the optical bezel area to an upper surface of the substrate extension 510 of the optical area OA.

In the process of forming the display panel 110, the second encapsulation layer PCL, which is an organic layer, can shrink due to factors such as heat and pressure after disposing the second encapsulation layer PCL. The second encapsulation layer PCL can cause a crack at a first point 701 and a lifting at a second point 702 due to the shrinkage. The lifting at the second point 702 can correspond to a point where the substrate extension 510 and the second encapsulation layer PCL are separated from each other and lifted in the optical area OA.

The substrate protrusion 820 can be disposed in the optical area OA to fill the first point 701 and the second point 702 of the second encapsulation layer PCL. For example, paste can be applied to the substrate extension 510 and then cured to fill the first point 701 and the second point 702. For example, the substrate protrusion 820 can be formed to cover a part of the side surface of the second encapsulating layer PCL. For example, the substrate protrusion 820 can be a paste of a glass material as described above. The paste of a glass material can be applied to the substrate extension 510 and heat-treated with a laser. The heat-treated paste can be melted and then seep into a gap between the first point 701 and the second point 702 of the second encapsulating layer PCL to fill the cracks and the raised portions. Thereafter, a hardening process can be performed to form a strong bonding structure with the second encapsulating layer PCL.

In addition, the substrate protrusion 820 can be disposed to contact a portion of the upper surface of the second encapsulation layer. A portion of the upper surface of the second encapsulation layer PCL on which the substrate protrusion 820 is disposed can be located on an optical bezel area (e.g., HiAA bezel area).

The substrate protrusions 720 and 820 of FIGS. 7 and 8 can be formed to fill the first point 701 and the second point 702 of the second encapsulation PCL, layer thereby preventing moisture penetration and crack penetration into the display area AA due to a crack in the first point 701 and a lifting in the second point 702 without expanding the width of the optical bezel area (e.g., HiAA bezel area).

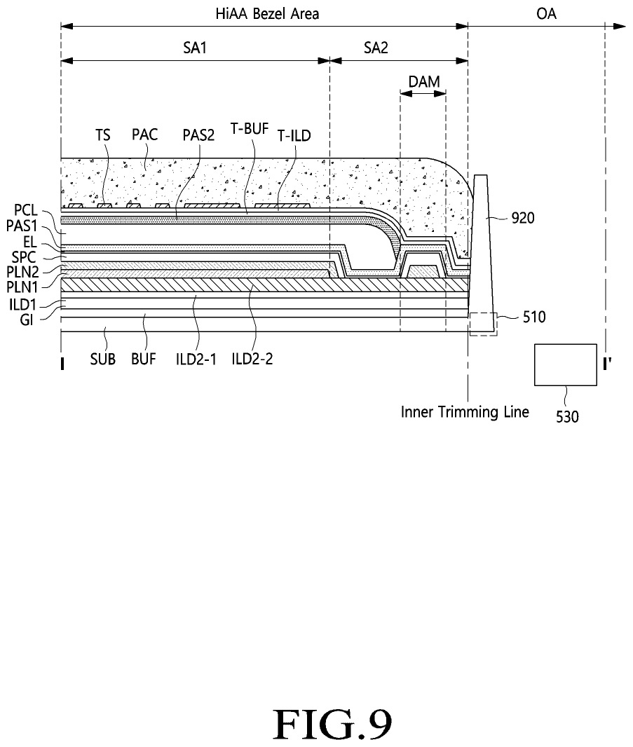

FIGS. 9, 10, 11, and 12 are cross-sectional views of an optical bezel area (e.g., HiAA bezel area) and an optical area OA in which a substrate protrusions 920, 1020, 1120 or 1220 is disposed in a display panel 110 with a touch sensor TS according to embodiments of the present disclosure.

Referring to FIG. 9, in addition to a configuration of the display device 100 for providing the same touch sensing function as FIG. 5, a substrate protrusion 920 can be disposed on the substrate extension 510.

The substrate protrusion 920 can be disposed in contact with a protective layer PAC in an optical area OA. More specifically, the protective layer PAC can be disposed in contact with a side of the substrate protrusion 920 in the optical area OA.

The substrate protrusion 920 can be disposed in a dam shape in the optical area OA. For example, the substrate protrusion 920 can be disposed by raising the substrate extension 510 by applying heat with a laser.

The substrate protrusion 920 can be formed in a dam shape on the substrate extension 510. For example, the substrate protrusion 920 can be formed in a trapezoidal dam shape in which a length of the lower area adjacent to the substrate extension 510 is greater than a length of the upper area. In addition, the substrate protrusion 920 can be formed to have a height greater than a width.

However, this is only an example of the shape of the substrate protrusion 920, and the shape of the substrate protrusion 920 is not limited thereto. For example, the substrate protrusion 920 can be formed in shapes such as a triangle, a rectangle, and an oval.

An optical area OA can be formed on the right side of the substrate protrusion 920. An optical electronic device 530 can be disposed in the optical area OA on the lower right side of the substrate protrusion 920.

In FIG. 9, configurations for forming a display panel 110 can be disposed on the substrate SUB in the left optical bezel area of the substrate protrusion 920.

For example, a buffer layer BUF, a gate insulating film GI, an interlayer insulating film ILD1, planarization layers PLN1 and PLN2, a spacer SPC, an emission layer EL, a first encapsulation layer PAS1, and a second encapsulation layer PCL can be disposed on the left substrate SUB of the substrate protrusion 920.

In additiona, a configuration for a touch sensing function can be disposed on the second encapsulation layer PCL in a left side of the substrate protrusion 920. For example, a touch buffer layer T-BUF, a touch insulating film T-ILD, a touch sensor TS can be disposed, and a protective layer PAC which is an organic layer for protecting the touch sensor TS can be disposed to cover the touch sensor TS.

In addition, a dam DAM can be disposed on the left area of the substrate protrusion 920. Specifically, the dam DAM can be disposed on the outer side of the second encapsulation layer PCL which is an organic layer. For example, the dam DAM can be disposed between the second encapsulation layer PCL and the substrate protrusion 920.

A part of the left side of the substrate protrusion 920 can be disposed so as to be in contact with the protective layer PAC which is an organic layer.

In this case, an upper surface of the substrate protrusion 920 can be located higher than a position where the protective layer PAC is in contact with the substrate protrusion 920. In this case, the substrate protrusion 920 can prevent the problem of the overflow of the protective layer PAC to the optical area OA.

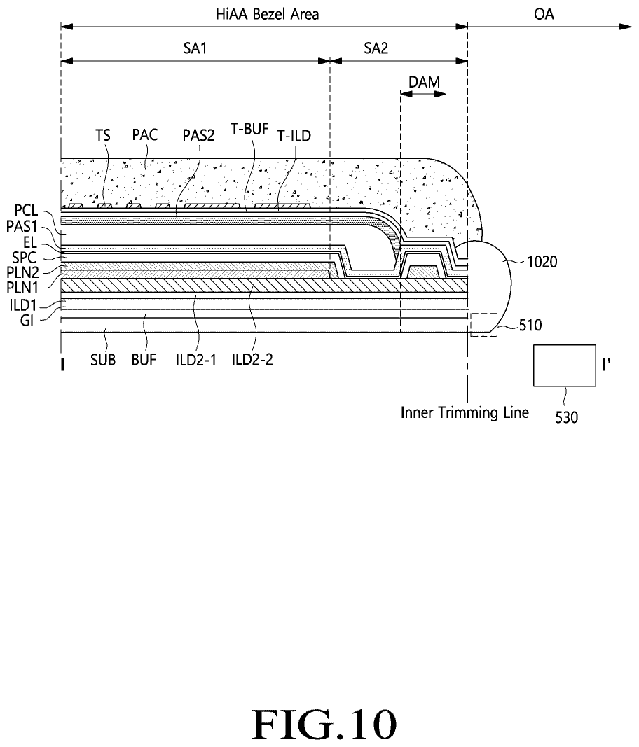

Referring to FIG. 10, a substrate protrusion 1020) can be disposed in a form other than a dam. For example, the substrate protrusion 1020 can be formed by applying paste to the substrate extension 510 and then curing the paste. In this case, the paste can be the same material as the substrate SUB. For example, the substrate SUB can be a glass material. The paste applied to the substrate extension 510 can also be a fine raw material of glass. The paste, which is a fine raw material of glass, can be applied to the substrate extension 510 and then melted by applying heat. In this case, a laser can be used as a means for heat-treating the paste. The paste heat-treated by the laser on the substrate extension 510 can melt and then penetrate under the protective layer (PAC). Alternatively, the heat- treated paste can be arranged to cover a portion of an upper surface of a touch insulating film T-ILD and a touch buffer layer T-BUF. Thereafter, the paste can be combined with the sides of each component of the display panel 110 through a curing process to form a structure for sealing the moisture permeation path.

The features of the configurations shown in FIG. 10 can be the same as the features of the configurations shown in FIG. 9 except for the substrate protrusion 1020. For example, with reference to FIG. 10, there can be disposed a buffer layer BUF, a gate insulating film GI, an interlayer insulating film ILD, a planarization layers PLN1 and PLN2, a spacer SPC, an emission layer EL, a first encapsulation layer PAS1, and a second encapsulation layer PCL on the left side of the substrate protrusion 1020.

In addition, a configuration for a touch sensing function can be disposed on the second encapsulation layer PCL in the left side of the substrate protrusion 1020. For example, a touch buffer layer T-BUF, a touch insulating film T-ILD, a touch sensor TS can be disposed, and a protective layer PAC which is an organic layer for protecting the touch sensor TS can be disposed to cover the touch sensor TS.

The substrate protrusion 1020 can be disposed to contact a portion of the upper surface of the touch insulating film T-ILD. A portion of the upper surface of the touch insulating film T-ILD on which the substrate protrusion 1020 is disposed can be located on an optical bezel area (e.g., HiAA Bezel Area).

In addition, a portion of the substrate protrusion 1020 can be disposed to contact the protective layer PAC. More specifically, a portion of the substrate protrusion 1020 can be disposed in the optical bezel area, and can be in contact with the protective layer PAC. For example, the substrate protrusion 1020 can be disposed between the protective layer PAC and the substrate extension 510.

In FIG. 10, an optical area OA can be formed on the right side of the substrate protrusion 1020. An optical electronic device 530 can be disposed in the optical area OA at the lower right side of the substrate protrusion 1020.

In addition, a dam DAM can be disposed on the left side of the substrate protrusion 1020. Specifically, the dam DAM can be disposed on the outer side of the second encapsulation layer PCL which is an organic layer. For example, the dam DAM can be disposed between the second encapsulation layer PCL and the substrate protrusion 1020.

The substrate protrusions 920 and 1020 of FIGS. 9 and 10 can separate the optical bezel area (e.g., HiAA bezel area) from the optical area OA, thereby preventing crack spreading and moisture penetration through the components disposed in the optical bezel area (e.g., HiAA bezel area) without expanding the optical bezel area.

Meanwhile, the sdisplay device can be formed with a recessed pattern 1100.

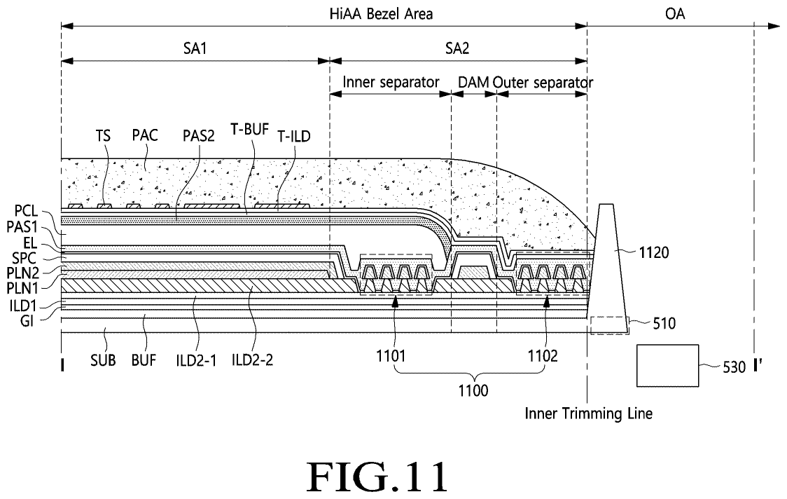

Referring to FIG. 11, the substrate SUB can be disposed in the optical bezel area (e.g., HiAA bezel area) and a part of the optical area OA. The substrate SUB can include a substrate extension 510 extending from the optical bezel area to a part of the optical area OA, and a substrate protrusion 1120 protruding from the optical substrate extension 510.

For example, the substrate protrusion 1120 can be disposed in a dam shape by raising the substrate extension 510 by applying heat with a laser. For example, the substrate protrusion 1120 can be formed in a trapezoidal dam shape in which a length of the lower area adjacent to the substrate extension 510 is longer and a length of the upper area is shorter. In addition, the substrate protrusion 1120 can be disposed so that the height is longer than the width.

However, this is only an example of the shape of the substrate protrusion 1120, and the shape of the substrate protrusion 1120 is not limited thereto. For example, the substrate protrusion 1120 can be formged in shapes such as a triangle, a rectangle, and an oval.

In FIG. 11, an optical area OA can be formed on the right side of the substrate protrusion 1120. An optical electronic device 530 can be disposed in the optical area OA on the lower right side of the substrate protrusion 1120.

With reference to FIG. 11, configurations for forming a display panel 110 capable of providing a touch sensing function can be formed on the substrate SUB in the left optical bezel area of the substrate protrusion 1120.

For example, there can be disposed a buffer layer BUF, a gate insulating film GI, an interlayer insulating film ILD1, a planarization layers PLN1 and PLN2, a spacer SPC, an emission layer EL, a first encapsulation layer PAS1, and a second encapsulation layer PCL on the substrate SUB in the left side of the substrate protrusion 1120.

In addition, a configuration for a touch sensing function can be disposed on the second encapsulation layer PCL in the left side of the substrate protrusion 1120. For example, a touch buffer layer T-BUF, a touch insulating film T-ILD, a touch sensor TS can be disposed, and a protective layer PAC which is an organic layer for protecting the touch sensor TS can be disposed to cover the touch sensor TS.

In addition, a dam DAM can be formed on a left area of the substrate protrusion 1120. Specifically, the dam DAM can be disposed on the outer side of the second encapsulation layer PCL which is an organic layer. For example, the dam DAM can be disposed between the second encapsulation layer PCL and the substrate protrusion 1120.

In addition, a recessed pattern 1100 can be further disposed on the substrate SUB of the optical bezel area (e.g., HiAA bezel area) in the left area of the substrate protrusion 1120.

The recessed pattern 1100 can be formed by removing at least a portion of an organic insulating layer (e.g., ILD2-2, PLN1, PLN2, etc.).

The emission layer EL can be located on the recessed pattern 1100, and the emission layer EL can be intermittently positioned on the recessed pattern 1100. For example, the emission layer EL can be disconnected by the recessed pattern 1100. Since the recessed pattern 1100 performs the function of disconnecting the emission layer, the recessed pattern 1100 can be is also referred to as a separator.

The first encapsulation layer PAS1 can be disposed on the emission layer EL in the optical bezel area. The first encapsulation layer PAS1 can fill a valley of the recessed pattern 1100.

The dam DAM can be disposed between the recessed pattern 1100 or on the outside of the second encapsulation layer PCL. The recessed pattern 1100 can be divided into an inner recessed pattern 1101 and an outer recessed pattern 1102.

The inner recessed pattern 1101 can be located in the direction to the display area AA from the dam DAM. The inner recessed pattern 1101 can be disposed to overlap with the second encapsulation layer PCL which is an organic layer. The outer recessed pattern 1102 can be positioned in the direction to the optical area OA from the dam DAM. For example, the outer recessed pattern 1102 can be disposed between the substrate protrusion 1120 and the dam DAM.

The recessed pattern 1100 and the dam DAM can be disposed in a second sub-area SA2. The protective layer PAC can extend from a first sub-area SAI to at least a portion of the second sub-area SA2.

In FIG. 11, the protective layer PAC is illustrated as being arranged to an area overlapping with the outer recessed pattern 1102, but is not limited thereto, and the protective layer PAC can be disposed to the dam DAM or the inner recessed pattern 1101.

Meanwhile, the substrate protrusion 1120 can be disposed in contact with the protective layer PAC. A part of the substrate protrusion 1120 can be disposed on the outer edge of the outer recessed pattern 1102. Alternatively, the substrate protrusion 1120 can be disposed in contact with the outer recessed pattern 1102 in the optical area OA.

In this case, the substrate protrusion 1120 can be formed so that the height of the upper surface is higher than a point where the protective layer PAC contacts the side surface of the substrate protrusion 1120. Therefore, there can be prevent a problem that the protective layer PAC which is an organic layer overflows into the optical area OA on the right side of the substrate protrusion 1120.

The substrate protrusion 1120 can also be formed in a form other than a dam.

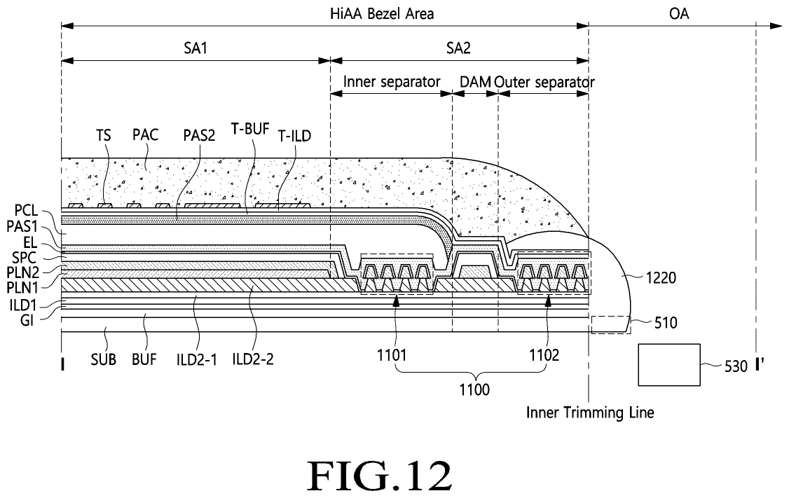

Referring to FIG. 12, for example, the substrate protrusion 1220 can be formed by applying paste to the substrate extension 510 and then curing the paste. The paste can be the same material as the substrate SUB. For example, the substrate SUB can be a glass material. The paste applied to the substrate extension 510 can also be a fine raw material of glass. The paste, which is a fine raw material of glass, can be applied to the substrate extension 510 and then melted by applying heat. At this time, a laser can be used as a means for heat-treating the paste. The paste heat-treated by the laser on the substrate extension 510 can melt and then penetrate under the protective layer PAC. Alternatively, the heat-treated paste can be disposed to cover a portion of the upper surface of a touch insulating film T-ILD and a touch buffer layer T-BUF. The paste can be heat-treated and then hardened to form the substrate protrusion 1220.

The features of the configuration excluding the substrate protrusion 1220 shown in FIG. 12 can be the same as the features of the configuration shown in FIG. 11. For example, based on FIG. 12, there can be disposed a buffer layer BUF, a gate insulating film GI, an interlayer insulating film ILD1, a planarization layer PLN1 and PLN2, a spacer SPC, an emission layer EL, a first encapsulation layer PAS1, and a second encapsulation layer PCL on the left side of the substrate protrusion 1220.

In FIG. 12, an optical area OA can be formed on the right side of the substrate protrusion 1220. An optical electronic device 530 can be disposed on the optical area OA in the lower right of the substrate protrusion 1220.

Further, a configuration for a touch sensing function can be disposed on the second encapsulation layer PCL on the left side of the substrate protrusion 1220. For example, a touch buffer layer T-BUF, a touch insulating film T-ILD, a touch sensor TS can be disposed, and a protective layer PAC which is an organic layer for protecting the touch sensor TS can be disposed to cover the touch sensor TS.

In addition, a dam DAM can be disposed on a left area of the substrate protrusion 1220. Specifically, the dam DAM can be disposed on the outer side of the second encapsulation layer PCL which is an organic layer. For example, the dam DAM can be disposed between the second encapsulation layer PCL and the substrate protrusion 1220.

The recessed pattern 1100 described in FIG. 11 can also be formed on the left area of the substrate protrusion 1220. Specifically, an inner recessed pattern 1101 can be disposed to overlap with the second encapsulation layer PCL which is an organic layer. An outer recessed pattern 1102 can be disposed in the direction of the optical area OA from the dam DAM. For example, the outer recessed pattern 1102 can be disposed between the substrate protrusion 1220 and the dam DAM. The substrate protrusion 1220 can replace the function and effect of the outer recessed pattern 1102, thereby reducing the physical length of the outer recessed pattern 1102. By forming the substrate protrusion 1220, it is possible to prevent moisture and crack penetration through the substrate protrusion 1220 without increasing the arrangement length of the outer recessed pattern 1102. Therefore, the physical length of the outer recessed pattern 1220 can be reduced to reduce the optical bezel area (e.g., HiAA bezel area).

The substrate protrusion 1220 can be disposed to overlap with the outer recessed pattern 1102 in the optical bezel area (e.g., HiAA bezel area). Specifically, the substrate protrusion 1220 can be disposed on the optical bezel area while covering the touch insulating film T-ILD in the area overlapping with the outer recessed pattern 1102. The substrate protrusion 1220 can be disposed in contact with the protective layer PAC in the optical bezel area (e.g., HiAA bezel area).

In addition, the protective layer PAC is illustrated as being arranged up to an area overlapping with the outer recessed pattern 1102, but is not limited thereto. The protective layer PAC can be disposed up to the dam DAM or the inner recessed pattern 1101.

The substrate protrusions 1120 and 1220 of FIGS. 11 and 12 can separate the optical bezel area (e.g., HiAA bezel area) from the optical area OA, thereby preventing crack penetration and moisture penetration through the components arranged in the optical bezel area without expanding the optical bezel area.

The features of the present disclosure shown in FIGS. 6 to 12 described above are embodiments related to the optical area OA where an optical electronic device 530 is disposed, but can also be applied to the non-display area NA surrounding the periphery of the display panel 110. For example, the substrate protrusions 620, 720, 820, 920, 1020, 1120 and 1220 shown in FIGS. 6 to 12 can be disposed at the boundary between the display area AA of the display panel 110 and the non-display area NA surrounding the periphery of the display panel 110, thereby preventing moisture and crack penetration that can occur from an outer edge of the display panel 110 into the display area AA.

Embodiments of the present disclosure described above are briefly described as follows.

A display device according to embodiments of the present disclosure can include a substrate including a non-display area having an optical area and an optical bezel area which is an outer area of the optical area, and a display area, a light emitting device disposed in the display area, and an organic layer disposed on the substrate. In this case, the substrate can include a substrate extension extending from the optical bezel area to a portion of the optical area, and a substrate protrusion protruding from the substrate extension in the optical area.

The organic layer can be disposed in contact with a portion of an upper surface of the substrate extension and a portion of a side surface of the substrate protrusion.

A position of an upper surface of the substrate protrusion can be higher than a position where the organic layer contacts the substrate protrusion.

The substrate protrusion can be disposed to cover a portion of a side surface of the organic layer.

The substrate protrusion can have a shape of a dam.

The substrate protrusion can be disposed in contact with a side surface of the organic layer and a portion of an upper surface of the organic layer.

The organic layer can include a crack, or a portion of the organic layer can be disposed spaced apart from the substrate extension in the optical area.

The display device according to embodiments of the present disclosure can further include a dam disposed on an outer surface of the organic layer, a touch sensor disposed on the organic layer, and a protective layer disposed to cover the touch sensor. The substrate protrusion can be disposed in contact with the protective layer.

The substrate protrusion can be disposed in the form of a dam in the optical area.

A portion of the substrate protrusion can be disposed in the optical bezel area, and can be disposed between the protective layer and the substrate extension.

The display device according to embodiments of the present disclosure can further include an inner recessed pattern disposed to overlap with the organic layer, and an outer recessed pattern disposed on an outer side of the dam. In this csse, a portion of the substrate protrusion can be disposed on an outer side of the outer recessed pattern.

The substrate protrusion can be disposed in contact with the outer recessed pattern in the optical area.

The substrate protrusion can be disposed to overlap with the outer recessed pattern in the optical bezel area.

The inner recessed pattern and the outer recessed pattern can include at least one uneven pattern.

The display device according to embodiments of the present disclosure can further include an optical electronic device disposed on the optical area.

The optical bezel area may comprise a first sub-area and a second sub-area between the first sub-area and the optical area, the inner recessed pattern, the outer recessed pattern and the dame are disposed in the second sub-area, and the protective layer extends from the first sub-area to at least a portion of the second sub-area.

The substrate protrusion can be formed by raising the substrate extension by applying heat with a laser.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a substrate including a display area and a non-display area, the non-display area having an optical area and an optical bezel area being an outer area of the optical area;
a light emitting device disposed in the display area; and
an organic layer disposed on the substrate,
wherein the substrate includes a substrate extension extending from the optical bezel area to a portion of the optical area, and a substrate protrusion protruding from the substrate extension in the optical area.

2. The display device of claim 1, wherein the organic layer is disposed in contact with a portion of an upper surface of the substrate extension and in contact with a portion of a side surface of the substrate protrusion.

3. The display device of claim 2, wherein a position of an upper surface of the substrate protrusion is located higher than a position where the organic layer contacts the substrate protrusion.

4. The display device of claim 1, wherein the substrate protrusion is disposed to cover a portion of a side surface of the organic layer.

5. The display device of claim 1, wherein the substrate protrusion has a shape of a dam.

6. The display device of claim 1, wherein the substrate protrusion is disposed in contact with a side surface of the organic layer and a portion of an upper surface of the organic layer.

7. The display device of claim 1, wherein the organic layer includes a crack, and/or a portion of the organic layer is disposed spaced apart from the substrate extension in the optical area.

8. The display device of claim 1, further comprising:
a dam disposed on an outer side of the organic layer;
a touch sensor disposed on the organic layer; and
a protective layer disposed to cover the touch sensor,
wherein the substrate protrusion is disposed in contact with the protective layer.

9. The display device of claim 8, wherein the substrate protrusion is disposed in a dam form in the optical area.

10. The display device of claim 8, wherein a portion of the substrate protrusion is disposed in the optical bezel area, and is disposed between the protective layer and the substrate extension.

11. The display device of claim 8, further comprising:
an inner recessed pattern disposed to overlap with the organic layer;
an outer recessed pattern disposed on an outer side of the dam,
wherein at least a portion of the substrate protrusion is disposed on an outer side of the outer recessed pattern.

12. The display device of claim 11, wherein the substrate protrusion is disposed in contact with the outer recessed pattern in the optical area.

13. The display device of claim 11, wherein the substrate protrusion is disposed to overlap with the outer recessed pattern in the optical bezel area.

14. The display device of claim 11, wherein each of the inner recessed pattern and the outer recessed pattern includes at least one recessed pattern.

15. The display device of claim 1, further comprising an optical electronic device disposed on the optical area.

16. The display device of claim 11, wherein the optical bezel area comprises a first sub-area and a second sub-area between the first sub-area and the optical area, the inner recessed pattern, the outer recessed pattern and the dame are disposed in the second sub-area, and the protective layer extends from the first sub-area to at least a portion of the second sub-area.

17. The display device of claim 1, wherein the substrate protrusion is formed by raising the substrate extension by applying heat with a laser.
